(19) United States
(12) Patent Application Publication
(10) Pub. No.: US 2024/0113017 A1
(43) Pub. Date: Apr. 4, 2024

(54) PLUG IN A METAL LAYER

(71) Applicant: Intel Corporation, Santa Clara, CA (US)

(72) Inventors: Leonard P. GULER, Hillsboro, OR (US); Gurpreet SINGH, Beaverton, OR (US); Charles H. WALLACE, Portland, OR (US); Tahir GHANI, Portland, OR (US)

(21) Appl. No.: 17/958,288

(22) Filed: Sep. 30, 2022

(51) Int. Cl. H01L 23/528; H01L 21/768

(52) U.S. Cl. CPC H01L 23/528; H01L 21/76892; H01L 21/76837; H01L 23/5226

(57) ABSTRACT

Embodiments described herein may be related to apparatuses, processes, systems, and/or techniques for forming a plug within a metal layer of a semiconductor device, where the plug is formed within a cavity that is created through the metal layer. The plug may extend through the metal layer and into a layer below the metal layer, which may be a layer that includes a dielectric and one or more electrical routing features. The plug may include an electrical insulator material. The cavity may be formed by placing a mask above the metal layer and performing an etch through the metal layer subsequently filled with a dielectric, where the plug will be tapered and wider at the top of the plug and become narrower as the plug continues through the metal layer and reaches the layer below the metal layer. Other embodiments may be described and/or claimed.

### FIELD

Embodiments of the present disclosure generally relate to the field of semiconductor manufacturing, and in particular to manufacturing transistor structures.

### BACKGROUND

Continued growth in virtual machines, cloud computing, and portable devices will continue to increase the demand for high density transistors within chips and packages. In addition, there will be an increased need for higher quality contacts between metal features within transistor structures.

### BRIEF DESCRIPTION OF THE DRAWINGS

FIGS. 1A-1G illustrate cross section side views of stages in a legacy manufacturing process for creating a legacy plug within a metal layer of a semiconductor device.

FIGS. 2A-2E illustrate cross section side views of stages in a manufacturing process for creating a plug within a metal layer of a semiconductor device, in accordance with various embodiments.

FIGS. 3A-3C illustrate perspective views of stages in a manufacturing process for creating a metal cut and plug within a semiconductor device, in accordance with various embodiments.

FIG. 4 illustrates a perspective view of an embodiment of a plug within a metal layer of a semiconductor device, in accordance with various embodiments.

FIG. 5 illustrates a perspective view of a legacy implementation of a legacy plug within a metal layer of a semiconductor device.

FIGS. 6A-6D illustrate perspective views of stages in the manufacturing process for creating a plug to electrically isolate source/drain metals using a metal cut and plug, in accordance with various embodiments.

FIG. 7 illustrates an example process for manufacturing a plug in a metal layer of a semiconductor device, in accordance with various embodiments.

FIG. 8 illustrates a computing device in accordance with one implementation of the invention.

FIG. 9 illustrates an interposer that includes one or more embodiments of the invention.

### DETAILED DESCRIPTION

Embodiments described herein may be related to apparatuses, processes, systems, and/or techniques for forming a plug within a metal layer of a semiconductor device, where the plug is formed within a cavity that is created through the metal layer. In embodiments, the plug may extend through the metal layer and into a layer below the metal layer, which may be a layer that includes a dielectric and one or more electrical routing features. In embodiments, a dielectric material may be placed within the cavity to form the plug.

In embodiments, the cavity may be formed by placing a mask above the metal layer and performing an etch through the metal layer. In embodiments, this may result in a tapered dimension of the plug that will be wider at the top of the plug and become narrower as the plug continues through the metal layer and reaches the layer below the metal layer. In embodiments, the plug may be used to terminate an electrical routing feature within the metal layer near where the electrical routing feature may electrically couple with an electrical routing feature in the layer below the metal layer.

For example, an electrical trace in the metal layer may electrically couple with a metal via in the layer below the metal layer. In embodiments, the dimensions of the plug may allow the plug to be smaller and to be closer to the location of the metal via due to the tapering of the plug. As a result, due to the tapering of the plug, there may be more surface area between the electrical trace and the metal at the surface of the metal via in the layer below the metal layer, unlike legacy plug implementations where legacy plug may overlap a portion of the surface of the metal via.

In legacy plug implementations, the metal layer may be formed by first creating one or more plugs in a dielectric layer by applying a mask and etching the dielectric layer through to an etch stop at the surface of the lower layer. A metal may then be deposited into the etched portion of the dielectric layer to form the legacy metal layer. A legacy plug will result where the dielectric layer was not etched. In this legacy implementation however, a taper of the legacy plug will be smaller at the top of the legacy metal layer and become larger as the legacy plug extends toward the lower layer. In these legacy implementations, legacy plugs may need to be spaced further apart in order for the bottom of the plug to not partially or fully block the surface of the metal via, or other metal structure, at the lower layer.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

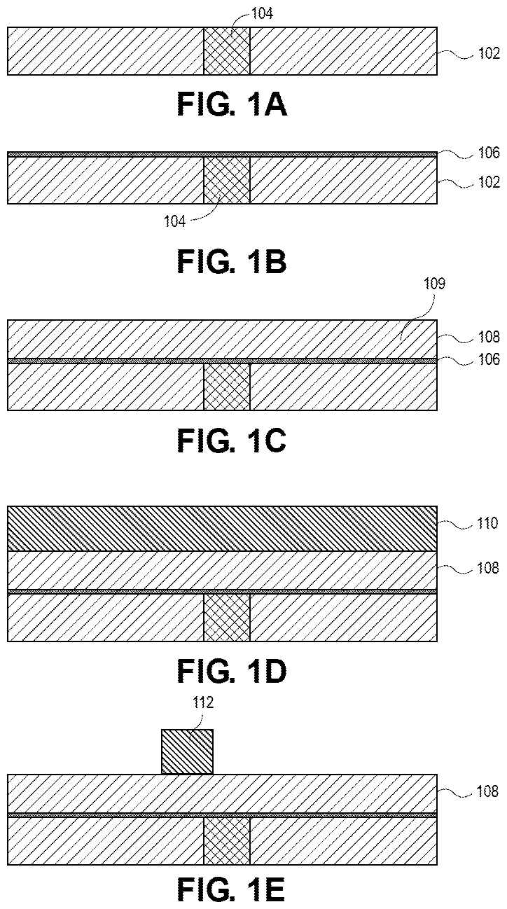

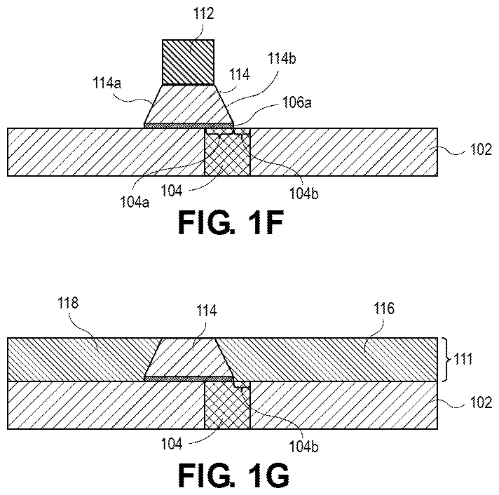

FIGS. 1A-1G illustrate cross section side views of stages in a legacy manufacturing process for creating a legacy plug within a metal layer of a semiconductor device. FIG. 1A shows a cross section side view of a stage in the legacy manufacturing process where a substrate 102 is provided. A metal via 104 may be provided that couples with a surface of the substrate 102.

FIG. 1B shows a cross section side view of a stage in the legacy manufacturing process where an etch stop 106 may be applied on a surface of the substrate 102 and on a surface of the metal via 104.

FIG. 1C shows a cross section side view of a stage in the legacy manufacturing process where a dielectric layer 108 may be placed on the etch stop 106. In embodiments, the dielectric layer 108 may include dielectric material 109. The dielectric material 109 may include SiO, SiN, SiOC, or SiOCN.

FIG. 1D shows a cross section side view of a stage in the legacy manufacturing process where a mask layer 110 is placed on the dielectric layer 108. In embodiments, the mask layer 110 may be a hard mask.

FIG. 1E shows a cross section side view of a stage in the legacy manufacturing process where a patterning of the mask layer 110 of FIG. 1D occurs, resulting in the plug mask 112 on the surface of the dielectric layer 108.

FIG. 1F shows a cross section side view of a stage in the legacy manufacturing process where an etching process of the dielectric layer 108 of FIG. 1E is performed. In embodiments, the etching may be an isotropic or a non-isotropic etching. As a result, a legacy plug 114 is formed beneath the plug mask 112. An etch stop portion 106a of the etch stop 106 of FIG. 1B remains beneath the legacy plug 114.

As a result of the etching process, sides 114a, 114b of legacy plug 114 taper outward, where a surface area of the legacy plug 114 immediately below the plug mask 112 will be significantly smaller than a surface area of the legacy plug 114 immediately above a top surface of the substrate 102 and a top surface of the metal via 104. As a result, a portion of the legacy plug 114 may partially cover a first region of the surface 104a of the metal via 104, and leave only a second region of the surface 104b of the metal via 104 exposed for electrical coupling.

FIG. 1G shows a cross section side view of a stage in the legacy manufacturing process where a first metal feature 116 and a second metal feature 118 is deposited on top of the substrate 102. The first metal feature 116, which may be a portion of a redistribution layer, may directly electrically couple with the metal via 104 only through the second region of the surface 104b of the metal via 104 that is exposed. Because the full surface of the metal via 104 is not directly electrically coupled with the first metal feature 116, the circuit represented by the first metal feature 116 and the metal via 104 may experience a higher electrical resistance, and thus impact performance or reliability of the circuit. In implementations, metal layer 111 may include the first metal feature 116, the second metal feature 118, and the legacy plug 114.

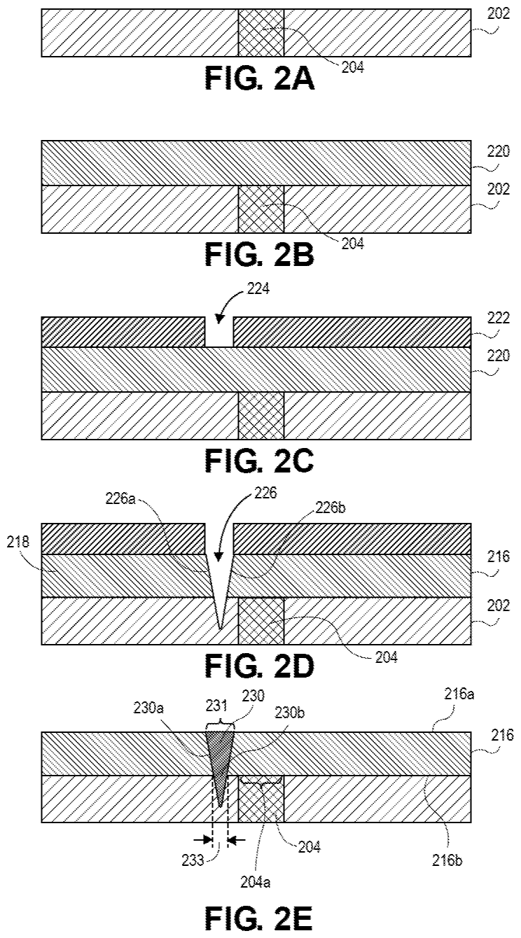

FIGS. 2A-2E illustrate cross section side views of stages in a manufacturing process for creating a plug within a metal layer of a semiconductor device, in accordance with various embodiments. FIG. 2A illustrates a cross section side view of a stage in the manufacturing process where a substrate 202 is provided. A metal via 204 may be provided that couples with a surface of the substrate 202. In embodiments, the substrate 202 and metal via 204 may be similar to substrate 102 and metal via 104 of FIG. 1A. In embodiments, the metal via 204 may be any type of electrically conductive feature that may be within the substrate 202. In embodiments, the substrate 202 may be a layer within another substrate (not shown).

FIG. 2B illustrates a cross section side view of a stage in the manufacturing process where a metal layer 220 may be placed on top of the substrate 202 and the metal via 204. In embodiments, the metal layer 220 may include copper, and may directly electrically couple with the metal via 204.

FIG. 2C illustrates a cross section side view of a stage in the manufacturing process where a mask 222 is placed on top of the metal layer 220, and a pattern 224, which may be referred to as a plug mask, is formed within the mask 222.

FIG. 2D illustrates a cross section side view of a stage in the manufacturing process where an etching process is performed to create a cavity 226. In embodiments, the etching process may include an isotropic etch or a non-isotropic etch. In embodiments, the cavity 226 may extend entirely through the metal layer 220 of FIG. 2C and may extend partially into the substrate 202, creating a first metal feature 216 and a second metal feature 218 that are electrically isolated from each other. In embodiments, the sides 226a, 226b of the cavity 226 may be tapered inward due to the nature of the etching process. In embodiments, a larger taper will facilitate the likelihood that the first metal feature 216 and the metal via 204 overlap.

FIG. 2E illustrates a cross section side view of a stage in the manufacturing process where the cavity 226 is filled with a plug 230, and the mask 222 of FIG. 2C is removed. In embodiments, the mask 222 may be removed using a polishing process. In embodiments, the cavity 226 of FIG. 2D may be filled with a dielectric material, or other material that include silicon, carbon, oxygen, nitrogen, SiC, SiO, SiN, SiOC, and/or SiNC to form plug 230.

In embodiments, sides 230a, 230b of the plug 230 may be tapered inward, similar to the sides 226a, 226b of the cavity 226 of FIG. 2D. As a result, the width of a first region 231 of the plug 230 at a top surface 216a of the first metal feature 216 may be greater than the width of a second region 233, which may be a cross-section, of the plug 230 at a bottom surface 216b of the first metal feature 216. In embodiments, a surface area of the first region 231 may also be greater than the surface area of the second region 233.

As a result of the tapering, the plug 230 will not intersect the metal via 204. This will allow the first metal feature 216 to fully electrically couple with the entire surface 204a of the metal via 204, or to completely overlap with the entire surface 204a of the metal via 204. In embodiments, the first region 231, or cross-section, of the plug 230 may partially overlap (not shown) the metal via 204, and still not intersect the metal via 204 due to the taper. In embodiments, this allows the plug 230 to be thinner than legacy plugs, such as legacy plug 114 of FIG. 1F, at the bottom surface 216b of the first metal feature 216.

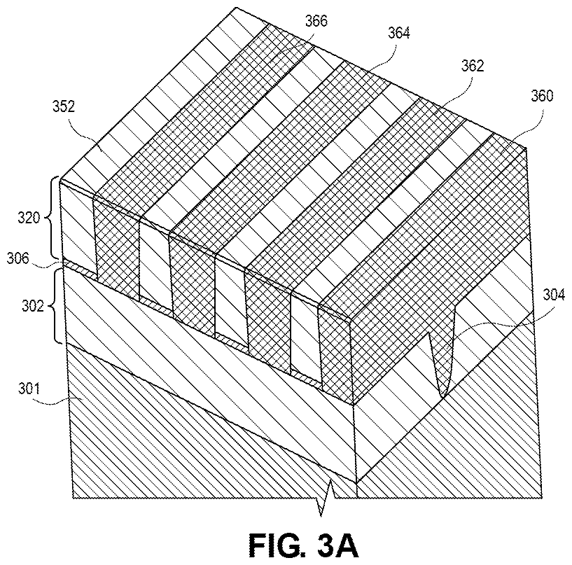

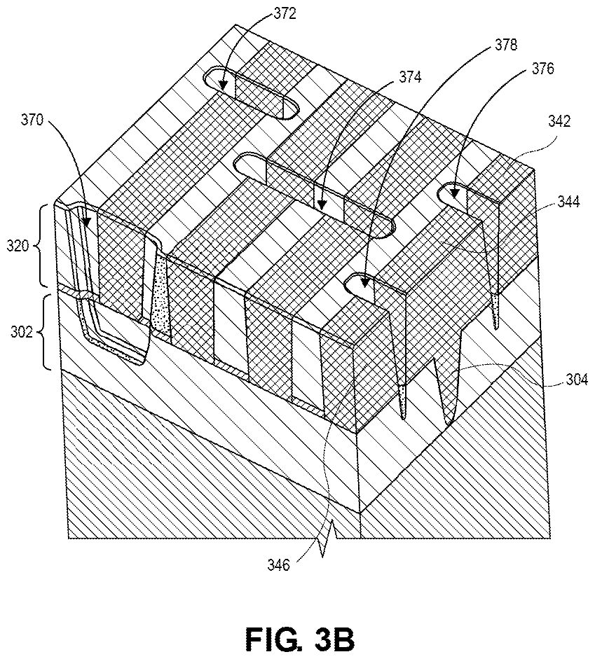

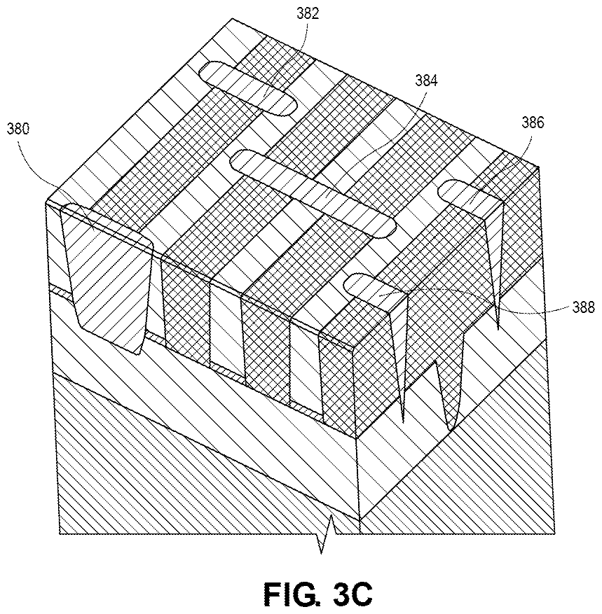

FIGS. 3A-3C illustrate perspective views of stages in a manufacturing process for creating a metal cut and plug within a semiconductor device, in accordance with various embodiments. FIG. 3A shows a perspective view of the semiconductor that has a base substrate 301 with a first layer 302 on the base substrate 301, and a metal layer 320 on top of the first layer 302. The first layer 302 and the metal layer 320 may be similar to substrate 202 and metal layer 220 of FIG. 2B. In embodiments, the first layer 302 may include a dielectric material. In embodiments, the first layer 302 may also include a metal via 304, which may be similar to metal via 204 of FIG. 2B, that may extend through the first layer 302.

Prior to the manufacturing stage shown in FIG. 3A, an etch stop 306, which may be similar to etch stop 106 of FIG. 1B, is placed on the surface of the first layer 302. A dielectric material 352 was then placed on top of the etch stop 306. Metal lines 360, 362, 364, 366 were then placed onto the metal layer 320 by etching through the dielectric material 352 down to and including the etch stop 306, and a metal subsequently placed into the etch areas (not shown). As shown, metal line 360 within the metal layer 320 directly electrically contacts the metal via 304 in the first layer 302.

FIG. 3B shows a perspective view of a stage in the manufacturing process where a plurality of cuts 370, 372, 374, 376, 378 are performed through the metal layer 320 and at least partially into the first layer 302. In embodiments, these cuts 370, 372, 374, 376, 378 may be performed using an etching process, which may be an isotropic or a non-isotropic etch. Cuts 370, 372, 374, 376, 378 may be similar to cavity 226 of FIG. 2D. Cuts 370, 372 are into metal line 366 of FIG. 3A, cut 374 is into metal lines 362, 364 of FIG. 3A, and cuts 376, 378 are into metal line 360 of FIG. 3A.

In embodiments, cuts 376, 378 separate metal line 360 of FIG. 3A into metal line segments 342, 344, 346 that are electrically isolated from each other. Metal line segment 344 is electrically coupled with the metal via 304. Cuts 376, 378 that extend through the metal layer 320 and at least partially into the first layer 302 are tapered with a larger opening at the top of the metal layer 320, getting progressively narrower as the cuts 376, 378 extend down into the first layer 302. As a result, the cuts 376, 378 do not intersect the metal via 304, and as a result the metal line segment 344 is able to fully cover and directly electrically couple with a top surface of the metal via 304.

FIG. 3C shows a perspective view of the stage in the manufacturing process where plugs 380, 382, 384, 386, 388 are placed, respectively, within the cuts 370, 372, 374, 376, 378 of FIG. 3B. In embodiments, the plugs 380, 382, 384, 386, 388 may include a dielectric or may include some other material that may be an electrical insulator.

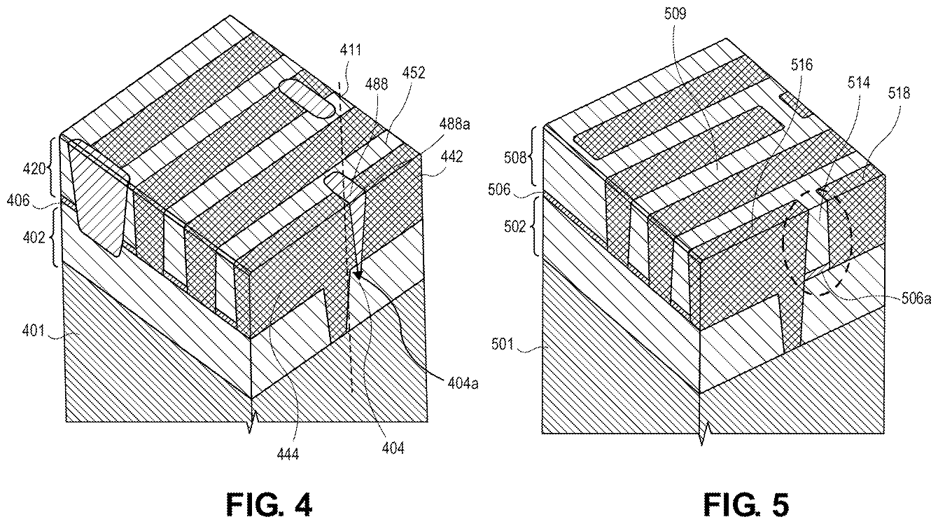

FIG. 4 illustrates a perspective view of an embodiment of a plug within a metal layer of a semiconductor device, in accordance with various embodiments. FIG. 4, which may be similar to FIG. 3C, shows a base substrate 401 onto which a first layer 402 is applied. In embodiments, a portion of a etch stop 406, may be applied to a top of the first layer 402 and beneath the metal layer 420, which is applied onto the first layer 402. The base substrate 401, first layer 402, and etch stop 406, may be similar to base substrate 301, first layer 302, and etch stop 306 of FIG. 3A.

In embodiments, a first metal line segment 444 that is part of the metal layer 420 is electrically isolated from a second metal line segment 442, also a part of the metal layer 420, by a plug 488. The first metal line segment 444 and the second metal line segment 442 may be next to a dielectric material 452 within the metal layer 420. The first metal line segment 444, second metal line segment 442, dielectric material 452, and plug 488 may be similar to metal line segments 344, 342, dielectric material 352, and plug 388 of FIG. 3C.

A portion of the plug 488 extends into the first layer 402. The first metal line segment 444 may be directly electrically coupled with a metal via 404, which may be similar to metal via 304 of FIG. 3A. The semiconductor device shown in FIG. 4 may be manufactured using techniques similar to the techniques described in FIGS. 2A-2E or the techniques described in FIGS. 3A-3C. As a result, a portion 488a of the plug 488 at a top of the metal layer 420 may be directly above a portion 404a of the metal via 404, as shown by the dashed line 411, while the plug does not intersect the metal via 404.

This is due to the tapering of the plug 488 from the top of the metal layer 420 down through the first layer 402. As a result, a smaller plug 488 may be used, and a more robust direct electrical contact may be made between the first metal line segment 444 and the metal via 404 due to the plug 488 not contacting the metal via 404. In addition, the plug 488 may be continuous material, for example a continuous dielectric, from the top of the metal layer 420 into the first layer 402. In particular, an etch stop, such as etch stop 406 of FIG. 4, is not required to form the plug 488, unlike the legacy implementation of a legacy plug described below with respect to FIG. 5 that may include an etch stop.

FIG. 5 illustrates a perspective view of a legacy implementation of a legacy plug within a metal layer of a semiconductor device. Unlike FIG. 4, FIG. 5 shows a legacy semiconductor device that includes a base substrate 501, a substrate 502, an etch stop 506, and a metal layer 508, which may be similar to substrate 102 and etch stop 106 of FIG. 1B, and dielectric layer 108 of FIG. 1C. Legacy plug 514, which may be similar to legacy plug 114 of FIG. 1F, is made from a dielectric material 509, which may be similar to dielectric material 109 of FIG. 1C, that was part of the initial layer of the metal layer 508 before metal line segments, such as metal line segment 516, 518, were formed into the dielectric 509 using legacy processes. The legacy processes may be similar to those shown with respect to FIGS. 1A-1G. Legacy plug 514 may be similar to legacy plug 114 of FIG. 1F.

Unlike plug 488 of FIG. 4, legacy plug 514 has a reverse taper, where a width, or a surface area, of the legacy plug 514 at a top of the metal layer 508 is smaller than a width, or a surface area, of the legacy plug 514 at the top of the substrate 502. In addition, etch stop portion 506a, may be between the legacy plug 514 and the substrate 502.

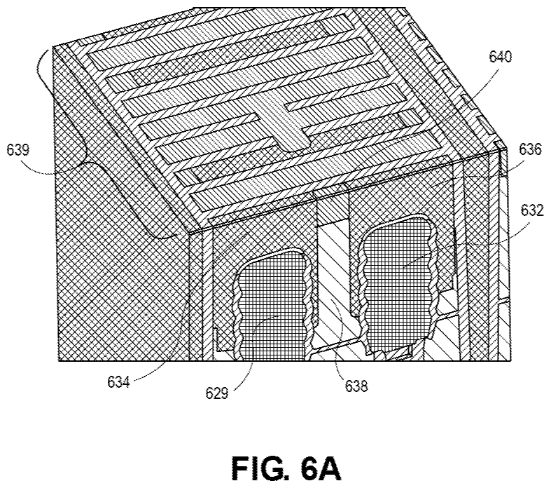

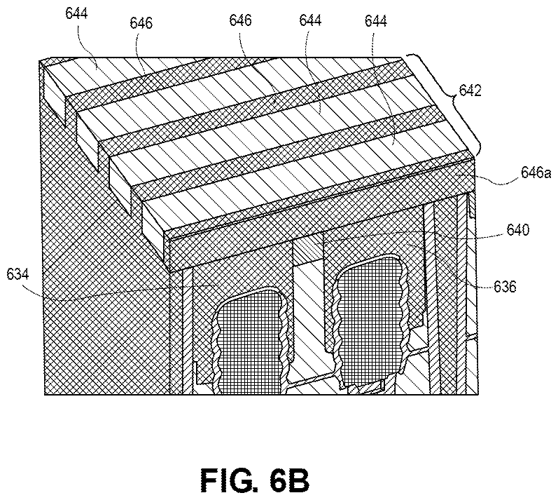

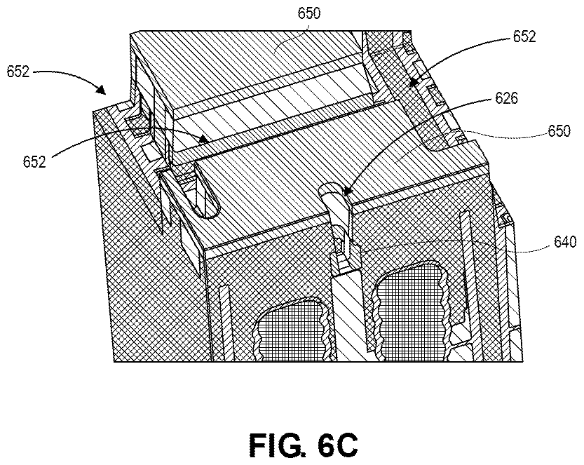

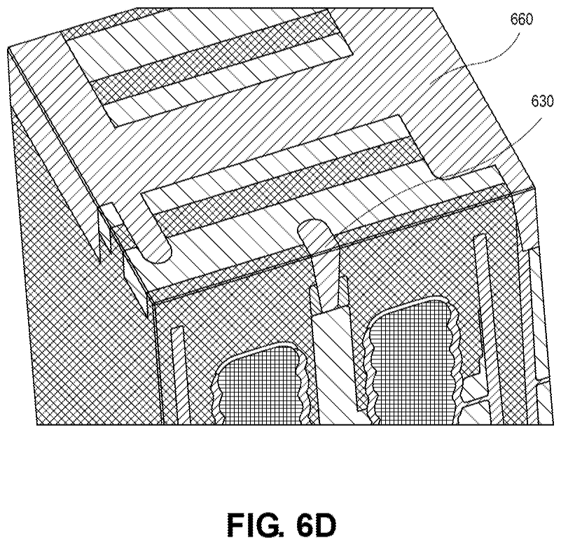

FIGS. 6A-6D illustrate perspective views of stages in the manufacturing process for creating a plug to electrically isolate source/drain metals using a metal cut and plug in a transistor structure, in accordance with various embodiments. FIG. 6A shows a perspective view of the stage in the manufacturing process of a transistor structure that includes a first epitaxial layer 629 that is surrounded by a first source/drain 634, and a second epitaxial layer 632 that is surrounded by a second source/drain 636. In embodiments, the first epitaxial layer 629 and the second epitaxial layer 632 may include silicon, germanium, gallium, and/or SiGe. In embodiments, the first source/drain 634 and the second source/drain 636 may include tungsten, cobalt, molybdenum, and/or ruthenium.

An insulator layer 638, and a cap 640 on the insulator layer 638 may electrically isolate the first source/drain 634 from the second source/drain 636. Other device features 639 may be behind the cap 640.

FIG. 6B shows a perspective view of a stage in the manufacturing process where a grating 642 is applied. In embodiments, the grating 642 may include layers of a dielectric 644 between layers of a metal 646. For example, metal 646a may be placed on the first source/drain 634 and the second source/drain 636, and above the cap 640.

FIG. 6C shows a perspective view of a stage in the manufacturing process where a hard mask 650 is applied, and an etching process is performed to form a metal gate cut by creating a cavity 652. The etching process also forms cavity 626, which may be similar to cavity 226 of FIG. 2D, through to cap 640.

FIG. 6D shows a perspective view of a stage in the manufacturing process where a material is applied to form plug 660 into the cavity 652 of FIG. 6C, and to form plug 630, which may be similar to plug 230 of FIG. 2E, into the cavity 626 of FIG. 6C.

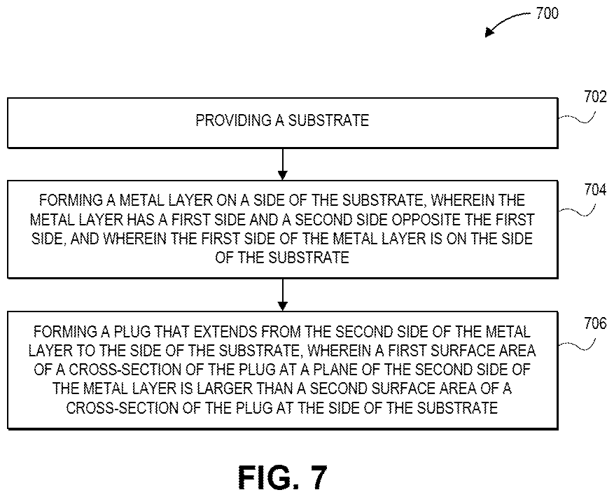

FIG. 7 illustrates an example process for manufacturing a plug in a metal layer of a semiconductor device, in accordance with various embodiments. Process 700 may be performed using the apparatus, systems, processes, tools, and/or techniques described herein and particularly with respect to FIGS. 1A-6D.

At block 702, the process may include providing a substrate. In embodiments, the substrate may be similar to substrate 202 of FIG. 2A, to first layer 302 of FIG. 3A, or to first layer 402 of FIG. 4.

At block 704, the process may further include forming a metal layer on a side of the substrate, wherein the metal layer has a first side and a second side opposite the first side, and wherein the first side of the metal layer is on the side of the substrate. In embodiments, the metal layer may be similar to metal layer 220 of FIG. 2B, metal layer 320 of FIG. 3A, or metal layer 420 of FIG. 4.

At block 706, the process may further include forming a plug that extends from the second side of the metal layer to the side of the substrate, wherein a first surface area of a cross-section of the plug at a plane of the second side of the metal layer is larger than a second surface area of a cross-section of the plug at the side of the substrate. In embodiments, the plug may be similar to plug 230 of FIG. 2E, plug 386 or plug 388 of FIG. 3C, or plug 488 of FIG. 4.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

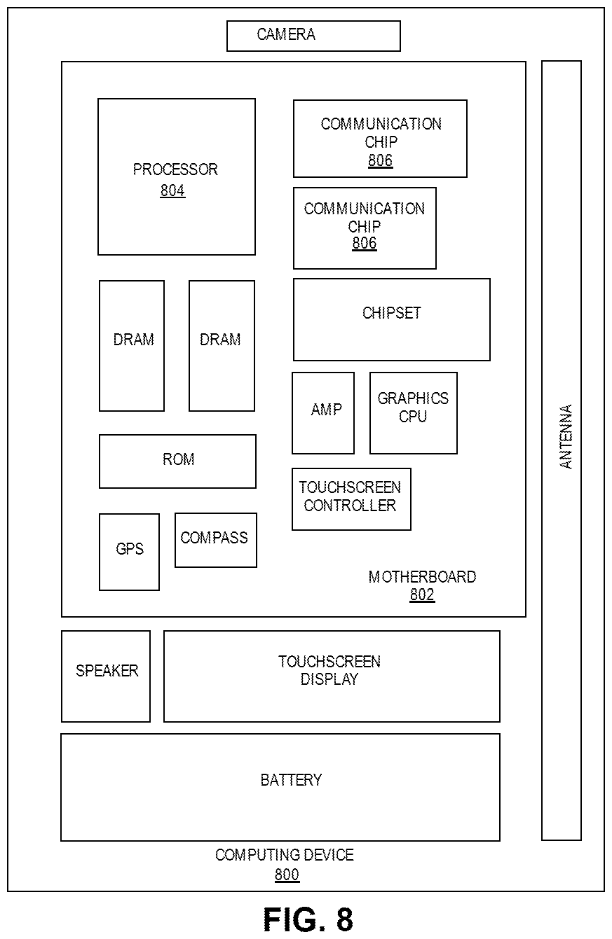

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip includes one or more devices, such as MOS-FET transistors built in accordance with implementations of the invention.

In further implementations, another component housed within the computing device 800 may contain an integrated circuit die that includes one or more devices, such as MOS-FET transistors built in accordance with implementations of the invention.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

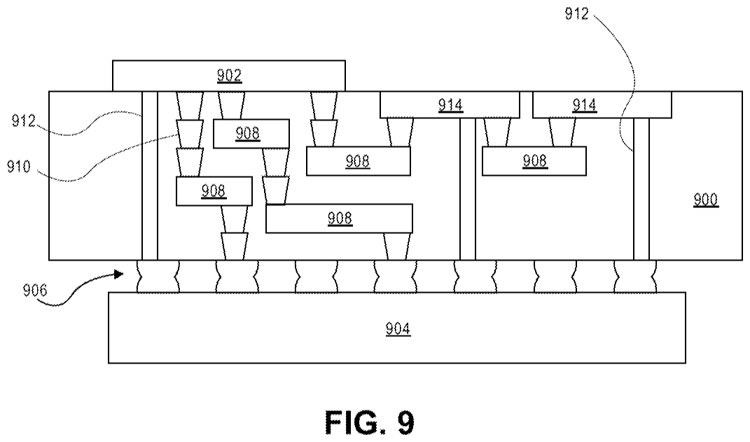

FIG. 9 illustrates an interposer 900 that includes one or more embodiments of the invention. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer 900 may be formed of alternate rigid or flexible materials that may include the same materials described above for use in a semiconductor substrate, such as silicon, germanium, and other group III-V and group IV materials.

The interposer may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the invention, apparatuses or processes disclosed herein may be used in the fabrication of interposer 900.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a semiconductor device comprising: a first layer with a first side and a second side opposite the first side; a second layer with a first side and a second side opposite the first side, wherein the first side of the second layer is on the second side of the first layer; and a plug that extends from the second side of the second layer to the second side of the first layer, wherein a first surface area of a cross-section of the plug at a plane of the second side of the second layer is larger than a second surface area of a cross-section of the plug at the second side of the first layer.

Example 2 includes the semiconductor device of example 1, wherein the first layer includes a first electrical routing feature at the second side of the first layer that is at least partially surrounded by a first dielectric, wherein the second layer includes a second electrical routing feature at the first side of the second layer that is at least partially surrounded by a second dielectric, wherein the first electrical routing feature is directly electrically coupled with the second electrical routing feature, and wherein the second electrical routing feature is adjacent to the plug.

Example 3 includes the semiconductor device of example 2, wherein the first electrical routing feature is a part of a metal via.

Example 4 includes the semiconductor device of examples 2 or 3, wherein the second electrical routing feature is part of a redistribution layer.

Example 5 includes the semiconductor device of examples 2, 3, or 4, wherein the second electrical routing feature completely overlaps a surface of the first electrical routing feature.

Example 6 includes the semiconductor device of examples 2, 3, 4, or 5, further comprising a third electrical routing feature at the first side of the second layer, wherein the third electrical routing feature is adjacent to the plug, and wherein the plug electrically isolates the second electrical routing feature and the third electrical routing feature from each other.

Example 7 includes the semiconductor device of examples 1, 2, 3, 4, 5, or 6, wherein the plug is direct physical contact with the first layer.

Example 8 includes the semiconductor device of examples 1, 2, 3, 4, 5, 6, or 7, wherein the plug extends into the first layer.

Example 9 includes the semiconductor device of examples 1, 2, 3, 4, 5, 6, 7, or 8, wherein the plug is an electrical insulator.

Example 10 includes the semiconductor device of examples 1, 2, 3, 4, 5, 6, 7, 8, or 9, wherein the plug includes a dielectric.

Example 11 is a semiconductor device comprising: a first epitaxial layer and a second epitaxial layer, wherein the first epitaxial layer is partially surrounded by a first metal and the second epitaxial layer is partially surrounded by a second metal; an insulator between the first metal and the second metal; and a plug that extends from a top of the first metal and a top of the second metal to a side of the insulator, wherein the plug and the insulator electrically isolate the first metal and the second metal from each other.

Example 12 includes the semiconductor device of example 11, wherein a first surface area of a cross-section of the plug at the top of the first metal and the top of the second metal is larger than a second surface area of a cross-section of the plug at the side of the insulator.

Example 13 includes the semiconductor device of examples 11 or 12, wherein the plug extends through the side of the insulator.

Example 14 includes the semiconductor device of examples 11, 12, or 13, wherein the first metal or the second metal includes tungsten.

Example 15 includes the semiconductor device of examples 11, 12, 13, or 14, wherein the plug includes a first dielectric and wherein the insulator includes a second dielectric.

Example 16 includes the semiconductor device of example 15, wherein the first dielectric and the second dielectric include different materials.

Example 17 is a method comprising: providing a substrate; forming a metal layer on a side of the substrate, wherein the metal layer has a first side and a second side opposite the first side, and wherein the first side of the metal layer is on the side of the substrate; and forming a plug that extends from the second side of the metal layer to the side of the substrate, wherein a first surface area of a cross-section of the plug at a plane of the second side of the metal layer is larger than a second surface area of a cross-section of the plug at the side of the substrate.

Example 18 includes the method of example 17, wherein forming the plug further includes: creating a cavity in the metal layer; and filling the cavity with a dielectric.

Example 19 includes the method of example 18, wherein creating the cavity further includes: placing a mask on the second side of the metal layer; and performing an etch through the metal layer.

Example 20 includes the method of examples 17, 18, or 19, wherein the plug extends into the substrate.

Example 21 includes the method of examples 17, 18, 19, or 20, wherein the metal layer includes copper.

What is claimed is:

1. A semiconductor device comprising:
a first layer with a first side and a second side opposite the first side;
a second layer with a first side and a second side opposite the first side, wherein the first side of the second layer is on the second side of the first layer; and
a plug that extends from the second side of the second layer to the second side of the first layer, wherein a first surface area of a cross-section of the plug at a plane of the second side of the second layer is larger than a second surface area of a cross-section of the plug at the second side of the first layer.

2. The semiconductor device of claim 1, wherein the first layer includes a first electrical routing feature at the second side of the first layer that is at least partially surrounded by a first dielectric,
wherein the second layer includes a second electrical routing feature at the first side of the second layer that is at least partially surrounded by a second dielectric,
wherein the first electrical routing feature is directly electrically coupled with the second electrical routing feature, and
wherein the second electrical routing feature is adjacent to the plug.

3. The semiconductor device of claim 2, wherein the first electrical routing feature is a part of a metal via.

4. The semiconductor device of claim 2, wherein the second electrical routing feature is part of a redistribution layer.

5. The semiconductor device of claim 2, wherein the second electrical routing feature completely overlaps a surface of the first electrical routing feature.

6. The semiconductor device of claim 2, further comprising a third electrical routing feature at the first side of the second layer, wherein the third electrical routing feature is adjacent to the plug, and wherein the plug electrically isolates the second electrical routing feature and the third electrical routing feature from each other.

7. The semiconductor device of claim 1, wherein the plug is direct physical contact with the first layer.

8. The semiconductor device of claim 1, wherein the plug extends into the first layer.

9. The semiconductor device of claim 1, wherein the plug is an electrical insulator.

10. The semiconductor device of claim 1, wherein the plug includes a dielectric.

11. A semiconductor device comprising:
a first epitaxial layer and a second epitaxial layer, wherein the first epitaxial layer is partially surrounded by a first metal and the second epitaxial layer is partially surrounded by a second metal;
an insulator between the first metal and the second metal; and
a plug that extends from a top of the first metal and a top of the second metal to a side of the insulator, wherein the plug and the insulator electrically isolate the first metal and the second metal from each other.

12. The semiconductor device of claim 11, wherein a first surface area of a cross-section of the plug at the top of the first metal and the top of the second metal is larger than a second surface area of a cross-section of the plug at the side of the insulator.

13. The semiconductor device of claim 11, wherein the plug extends through the side of the insulator.

14. The semiconductor device of claim 11, wherein the first metal or the second metal includes tungsten.

15. The semiconductor device of claim 11, wherein the plug includes a first dielectric and wherein the insulator includes a second dielectric.

16. The semiconductor device of claim 15, wherein the first dielectric and the second dielectric include different materials.

17. A method comprising:
providing a substrate;
forming a metal layer on a side of the substrate, wherein the metal layer has a first side and a second side opposite the first side, and wherein the first side of the metal layer is on the side of the substrate; and
forming a plug that extends from the second side of the metal layer to the side of the substrate, wherein a first surface area of a cross-section of the plug at a plane of the second side of the metal layer is larger than a second surface area of a cross-section of the plug at the side of the substrate.

18. The method of claim 17, wherein forming the plug further includes:
creating a cavity in the metal layer; and
filling the cavity with a dielectric.

19. The method of claim 18, wherein creating the cavity further includes:
placing a mask on the second side of the metal layer; and
performing an etch through the metal layer.

20. The method of claim 17, wherein the plug extends into the substrate.

21. The method of claim 17, wherein the metal layer includes copper.
